(19) United States
(12) Patent Application Publication
(10) Pub. No.: US 2011/0124382 A1
(43) Pub. Date: May 26, 2011

(54) MOBILE PHONE

(75) Inventors: Woon-Chun Kim, Suwon-si (KR); Soon-Gyu Yim, Seongnam-si, Gyeonggi-do (KR); Won-Tae Choi, Hwasung-si (KR)

(73) Assignee: SAMSUNG ELECTRO-MECHANICS CO., LTD.

(21) Appl. No.: 12/755,764

(22) Filed: Apr. 7, 2010

(30) Foreign Application Priority Data
Nov. 24, 2009 (KR) 10-2009-0114190

(51) Int. Cl. H04B 1/38; H01L 31/00

(52) U.S. Cl. 455/572; 136/256

(57) ABSTRACT

Disclosed is a mobile phone that includes a body having a base layer formed on one surface thereof and a dye-sensitized solar cell mounted on one surface of the body to face the base layer and providing electricity to the body. The dye-sensitized solar cell includes a first transparent substrate, a first electrode, a second electrode, a light absorption layer, a catalytic layer, an electrolyte and a second substrate, and the base layer forms a background against a pattern formed by a dye such that the pattern can be identified when viewed from the outside.

### CROSS-REFERENCE TO RELATED APPLICATIONS

This application claims the benefit of Korean Patent Application No. 10-2009-0114190, filed with the Korean Intellectual Property Office on Nov. 24, 2009, the disclosure of which is incorporated herein by reference in its entirety.

### BACKGROUND

1. Technical Field

The present invention is related to a mobile phone.

2. Description of the Related Art

Solar cells, which generate electrical energy by using solar energy, can use an infinite source of energy and are durable and environmentally friendly. Some examples of solar cells include silicon solar cells, semiconductor compound solar cells and dye-sensitive solar cells.

Here, in the dye-sensitized solar cell, dye molecules interposed between a pair of electrodes convert sunlight to electrons by absorbing the sunlight.

The dye molecules of the dye-sensitized solar cell can be appropriately arranged to form an identifiable pattern when viewed from the outside. Nevertheless, the pattern may not be recognized from the outside by external factors such as the viewing angle.

### SUMMARY

The present invention provides a dye-sensitized solar cell that allows a specific pattern formed by a dye to be effectively indentified when viewed from the outside, and a mobile device including the same.

An aspect of the present invention provides a mobile phone that includes a body having a base layer formed on one surface thereof and a dye-sensitized solar cell, which is mounted on one surface of the body to face the base layer and provides electricity to the body. Here, the dye-sensitized solar cell includes a first substrate, which is transparent and in which an inner surface of the first substrate faces the base layer, a first electrode, in which an inner surface of the first electrode is in contact with an outer surface of the first substrate, a second electrode, which is spaced apart from the first electrode and in which an inner surface of the second electrode faces an outer surface of the first electrode, a light absorption layer, which is in contact with one of the first electrode and the second electrode and in which the light absorption layer includes metal oxide and a dye which is adhered to the metal oxide such that the dye forms a specific pattern, a catalytic layer, which is in contact with the other of the first electrode and the second electrode and in which the catalytic layer faces the light absorption layer, an electrolyte, which is interposed between the first electrode and the second electrode, and a second substrate, in which an inner surface of the second substrate is in contact with an outer surface of the second electrode, and the base layer forms a background against a pattern formed by the dye such that the pattern can be identified when viewed from the outside.

The base layer can be formed by including a fluorescent or phosphorescent substance.

The base layer can be formed by including a dye or pigment with a specific color.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a front view of a mobile phone in accordance with an embodiment of the present invention.

FIG. 2 is a real view of a mobile phone in accordance with an embodiment of the present invention.

FIG. 3 is a cross-sectional view, based on an enlarged transverse section A-A of FIG. 2, illustrating a mobile phone's body and a dye-sensitized solar cell separated from each other.

FIG. 4 shows a structure of a dye-sensitized solar cell in accordance with another embodiment of the present invention.

### DETAILED DESCRIPTION

A mobile phone according to certain embodiments of the present invention will be described below in more detail with reference to the accompanying drawings. Those components that are the same or are in correspondence are rendered the same reference numeral regardless of the figure number, and redundant descriptions are omitted.

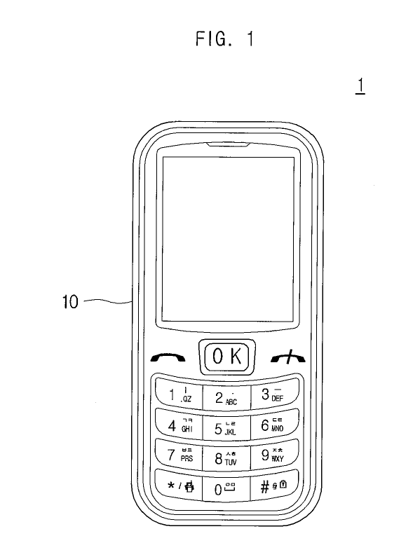

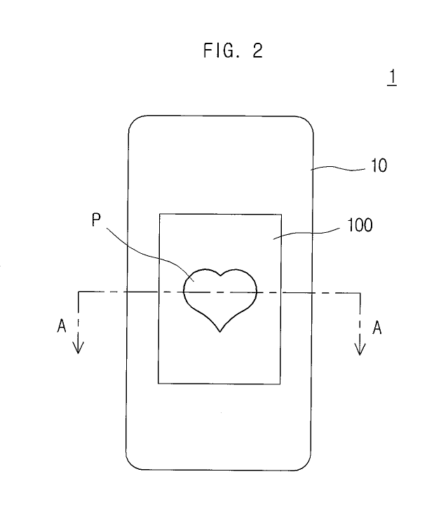

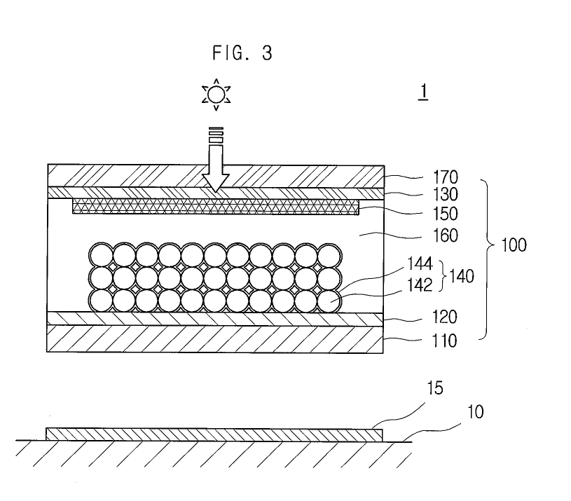

FIG. 1 is a front view of a mobile phone in accordance with an embodiment of the present invention, and FIG. 2 is a real view of a mobile phone in accordance with an embodiment of the present invention. FIG. 3 is an enlarged transverse section A-A of FIG. 2 and shows a mobile phone's body and a dye-sensitized solar cell separated from each other.

Referring to FIGS. 1 and 2, a mobile phone 1 of the present embodiment can include a body 10 and a dye-sensitized solar cell 100.

The body 10 can include various electronic components (not shown), which are used in implementing the functions of the mobile phone 1.

Referring to FIG. 3, a base layer 15 can be formed on one surface of the body 10 of the mobile phone 1. In the present embodiment, the base layer 15 is formed on a rear surface of the body 10, but is not limited to this embodiment.

The base layer 15 functions to have a pattern that is formed by a dye included in a dye-sensitized solar cell 100, which will be described later, to be effectively indentified when viewed from the outside. The base layer 15 will be described in more detail later.

In this embodiment, the dye-sensitized solar cell 100 can be mounted on one surface of the body 10 on which the base layer 15 is formed. In this case, the dye-sensitized solar cell 100 can be disposed to face the base layer 15.

The dye-sensitized solar cell 100 can be mounted removably or permanently on the body 10 of the mobile phone 1. The dye-sensitized solar cell 100 is electrically connected to the body 10 and supplies electricity for implementing the functions of the mobile phone 1 to the body 10.

In this embodiment, by mounting the dye-sensitized solar cell 100 rather than a silicon solar cell, which includes a silicon wafer, on the body 10, the entire mobile phone 1 becomes thinner, and the cost of manufacturing the mobile phone 1 becomes reduced.

Hereinafter, the structure of the dye-sensitized solar cell 100 of the present embodiment will be described by referring to FIG. 3. The dye-sensitized solar cell 100 can be constituted by a first substrate 110, a first electrode 120, a second electrode 130, a light absorption layer 140, a catalytic layer 150, an electrolyte 160 and a second substrate 170.

An inner surface of the first substrate 110 can face the base layer 15. The first substrate 110 is transparent and can be made of glass or high polymer such as PET.

The first electrode 120 can be disposed on an outer surface of the first substrate 110. In this case, an inner surface of the first electrode 120 can be in contact with the outer surface of the first substrate 110.

The second electrode 130 can be disposed to face an outer surface of the first electrode 120. Specifically, an inner surface of the second electrode 130 can face the outer surface of the first electrode 120. In this case, the second electrode 130 can be spaced apart from the first electrode 120.

The first electrode 120 and the second electrode 130 can each be formed by including Indium Tin Oxide (ITO), Fluorine-doped Tin Oxide (FTO), Carbon Nano Tube (CNT) or Graphene. The first electrode 120 and the second electrode 130 can have conductivity and be transparent.

Referring to FIG. 3, the light absorption layer 140 can be formed on the outer surface of the first electrode 120. In this case, the light absorption layer 140 can be in contact with the first electrode 120.

The light absorption layer 140 can be formed by including metal oxide 142 and a dye 144, which is adhered to the metal oxide 142. When the sunlight incident from the outside of the second substrate 170, which will be described later, is absorbed in the dye 144, the dye 144 changes electrons from a ground state to an exited state, creating electron-hole pairs. The electron in the excited state are injected into a conduction band of an interface between particles of the metal oxide 142, and the injected electrons are transferred to the first electrode 120 along the interface between particles of the metal oxide 142 and are moved to the second electrode 130 through an external circuit (not shown).

The dye 144, which is oxidized by electronic transition, can be deoxidized by iodine oxidation-reduction pairs (I₃⁻/I⁻) in the electrolyte 160, which will be described later. The oxidized iodine oxidation-reduction pairs have a reduction reaction with electrons arrived at an interface of the second electrode 130 to achieve charge neutrality, operating the dye-sensitized solar cell 100 as a result.

In this embodiment, the dye 144 included in the light absorption layer 140 forms a specific pattern. Here, the pattern shall mean a shape and color that can be identified from the outside. For example, as illustrated in FIG. 2, the dye-sensitized solar cell 100 can form a specific pattern P (refer to FIG. 3), which has the color of red (not shown) and the shape of a heart, by the dye 144 when viewed from the outside.

Referring to FIG. 3, the catalytic layer 150 can be formed on the inner surface of the second electrode 130. In this case, the catalytic layer 150 can be in contact with the second electrode 130. The catalytic layer 150 can be formed by including platinum (Pt), carbon, Carbon Nano Tube (CNT) or Graphene.

The electrolyte 160 can be interposed between the first electrode 120 and the second electrode 130. The electrolyte 160 can be made of an electrolyte aqueous solution of I₃⁻/I⁻ in which an iodine oxidation-reduction liquid electrolyte, for example, 1-vinyl-3-methyl-imidazolium iodide, 0.1 mol LiI, 40 m-mol I_{Z} (iodine) and 0.2 mol tert-butyl pyridine, are dissolved in 3-methoxypropionitrile. However, the electrolyte 160 is not limited to this example.

The dye-sensitized solar cell 100 formed through the above processes can be disposed to face the base layer 15 formed on one surface of the body 10 of the mobile phone 1. The base layer 15 forms a background against a pattern formed by the dye 144 of the dye-sensitized solar cell 100 so that the pattern can be effectively indentified when viewed from the outside.

The base layer 15 can be formed by including a fluorescent or phosphorescent substance. Here, the base layer 15 can absorb the sunlight transmitted through the dye-sensitized solar cell 100 to emit light. In this case, since the light-emitting base layer 15 is disposed on an inner side of the light absorption layer 140 (that is, on a lower side, as shown in FIG. 3), the base layer 15 can form a background against the pattern formed by the dye 144. Accordingly, the pattern formed by the dye 144 can be effectively identified from the outside.

Particularly, if the base layer 15 is made of a phosphorescent material, the base layer 15 that is exposed to the sunlight can emit light for a certain period of time even in a dark place so that the pattern formed by the dye 144 can be effectively identified in the dark place.

The base layer 15 can be formed by including a dye or pigment with a specific color, instead of the fluorescent or phosphorescent material. Here, the specific color refers to the color of a background against a pattern formed by the dye 144 included in the light absorption layer 140 to make the pattern stand out.

In one example, the base layer 15 can be formed by including a dye or pigment with the color of white or pale yellow. Since the base layer 15 is disposed on an inner side of the light absorption layer 140, the pattern formed by the dye 144 can be effectively identified when viewed from the outside.

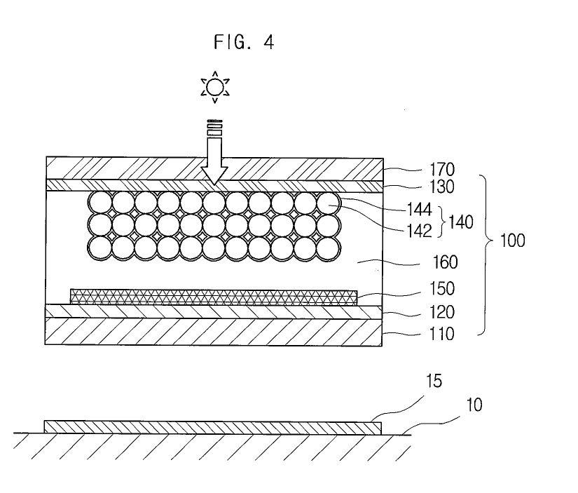

In this embodiment, the light absorption layer 140 is in contact with the first electrode 120, and the catalytic layer 150 is in contact with the second electrode 130. However, this configuration in only an example, and the light absorption layer 140 can be in contact with the second electrode 120, as illustrated in FIG. 4. Likewise, the catalytic layer 150 can be in contact with the first electrode 110.

While the spirit of the present invention has been described in detail with reference to particular embodiments, the embodiments are for illustrative purposes only and shall not limit the present invention. It is to be appreciated that those skilled in the art can change or modify the embodiments without departing from the scope and spirit of the present invention.

As such, many embodiments other than those set forth above can be found in the appended claims.

What is claimed is:

1. A mobile phone comprising:
a body having a base layer formed on one surface thereof; and
a dye-sensitized solar cell mounted on one surface of the body to face the base layer and configured to provide electricity to the body,
wherein the dye-sensitized solar cell comprises:
a first substrate being transparent, an inner surface of the first substrate facing the base layer;
a first electrode, an inner surface of the first electrode being in contact with an outer surface of the first substrate;
a second electrode spaced apart from the first electrode, an inner surface of the second electrode facing an outer surface of the first electrode;
a light absorption layer being in contact with one of the first electrode and the second electrode, the light absorption layer comprising metal oxide and a dye which is adhered to the metal oxide such that the dye forms a specific pattern;
a catalytic layer being in contact with the other of the first electrode and the second electrode, the catalytic layer facing the light absorption layer;
an electrolyte interposed between the first electrode and the second electrode; and
a second substrate, an inner surface of the second substrate being in contact with an outer surface of the second electrode, and
the base layer forms a background against a pattern formed by the dye such that the pattern can be identified when viewed from the outside.

2. The mobile phone of claim 1, wherein the base layer is formed by including a fluorescent or phosphorescent substance.

3. The mobile phone of claim 1, wherein the base layer is formed by including a dye or pigment with a specific color.
